(19) United States
(12) Patent Application Publication
(10) Pub. No.: US 2008/0172869 A1
(43) Pub. Date: Jul. 24, 2008

(54) METHODS AND SYSTEMS FOR PROCESSING SEMICONDUCTOR WORKPIECES

(75) Inventors: Kia Heng Puah, Singapore (SG); Liang Chee Tay, Singapore (SG)

Correspondence Address: PERKINS COIE LLP;PATENT-SEA, PO BOX 1247, SEATTLE, WA, 98111-1247, US

(73) Assignee: Micron Technology, Inc., Boise, ID (US)

(21) Appl. No.: 11/742,419

(22) Filed: Apr. 30, 2007

(30) Foreign Application Priority Data
Jan. 23, 2007 (SG) 200700517-6

(51) Int. Cl. H05K 3/30; H05K 13/04; B23P 19/00

(52) U.S. Cl. 29/832; 438/460; 257/E21.532; 29/834; 29/426.5; 438/458; 29/762

(57) ABSTRACT

Methods and systems for processing semiconductor workpieces are disclosed herein. In one embodiment, a method for processing a semiconductor workpiece includes releasably attaching a plurality of microelectronic dies to a first side of a releasable film, and at least partially detaching one of the dies from the releasable film by pivoting a contact member with a surface of the contact member pressing against a second side of the releasable film.

### CROSS-REFERENCE TO RELATED APPLICATION

This application claims foreign priority benefits of Singapore Application No. 200700517-6 filed Jan. 23, 2007, which is incorporated herein by reference in its entirety.

### TECHNICAL FIELD

The present disclosure is related to methods and systems for processing semiconductor workpieces; several examples of such methods and systems are directed to at least partially detaching a microelectronic die from a releasable film.

### BACKGROUND

Processors, memory devices, imagers, and other types of microelectronic devices are often manufactured on semiconductor workpieces or other types of workpieces. In a typical application, several individual dies (e.g., devices) are fabricated on a single workpiece using sophisticated and expensive equipment and processes. Individual dies generally include an integrated circuit and a plurality of bond-pads coupled to the integrated circuit. The bond-pads provide external electrical contacts on the die through which supply voltage, signals, etc., are transmitted to and from the integrated circuit. The bond-pads are usually very small, and they are arranged in an array having a fine pitch between bond-pads. The dies can also be quite delicate. As a result, after fabrication, the dies are packaged to protect the dies and to connect the bond-pads to another array of larger terminals that is easier to connect to a printed circuit board. The package can then be electrically connected to other microelectronic devices or circuits in many types of consumer or industrial electronic products.

Electronic product manufacturers are under continuous pressure to reduce the size of their products. Accordingly, microelectronic die manufacturers seek to reduce the size of the packaged dies incorporated into the electronic products. One approach to reducing the size of the packaged dies is to reduce the thickness of the dies. For example, the backside of a wafer is often ground to reduce the thickness of the dies formed on the wafer. After backgrinding, the wafer is attached to a wafer mounting tape and then cut to singulate the dies. A drawback with this approach is that the thin dies are extremely fragile and difficult to handle.

One conventional device for detaching dies from the wafer mounting tape includes an array of pins that are aligned with a particular die and press against the backside of the tape to detach the die from the tape. One problem with this device is that the pins can crack the thin die because the individual pins exert a force over a relatively small area. Another conventional device for detaching dies from the wafer mounting tape includes a ramp that moves vertically to press against the backside of the tape while the tape and dies move horizontally across the ramp. One problem with this device is the ramp may bend the thin dies, which can also crack the dies. Accordingly, there is a need to improve the handling of semiconductor workpieces during processing.

### BRIEF DESCRIPTION OF THE DRAWINGS

FIG. 1 is a schematic side cross-sectional view of a system for processing a semiconductor workpiece having a plurality of microelectronic dies in accordance with one embodiment of the disclosure.

FIG. 2 is a schematic isometric view of the contact assembly of FIG. 1.

FIGS. 3-5 illustrate stages in a method for detaching a die from the support structure in accordance with one embodiment of the disclosure.

FIG. 6 is a schematic isometric view of a contact assembly in accordance with another embodiment of the disclosure.

FIG. 7 is a schematic side view of a contact member in accordance with another embodiment of the disclosure.

FIG. 8 is a schematic side view of a contact member in accordance with another embodiment of the disclosure.

FIG. 9 is a schematic side view of a contact member in accordance with another embodiment of the disclosure.

### DETAILED DESCRIPTION

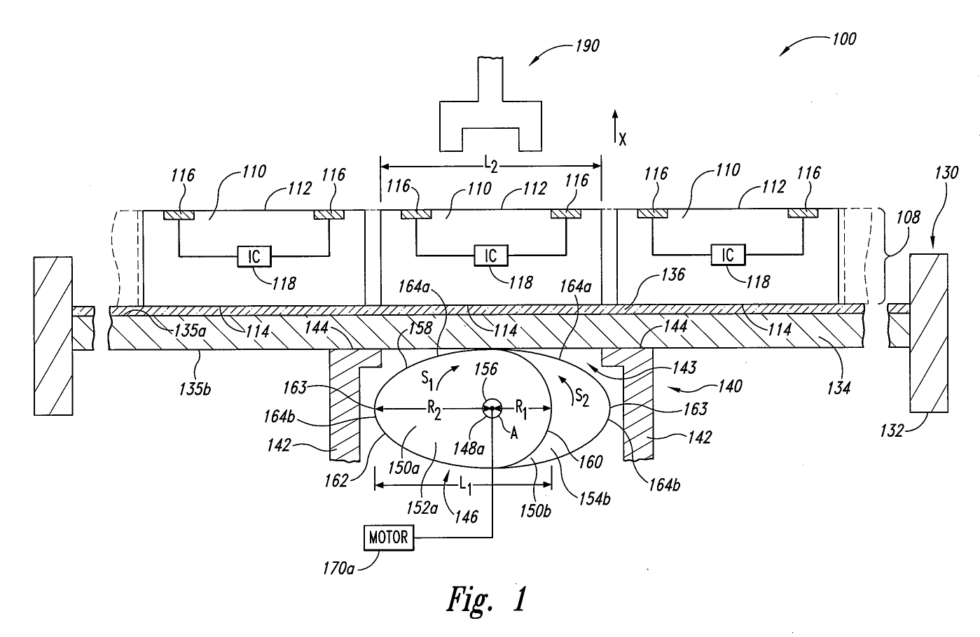

Specific details of several embodiments of the disclosure are described below with reference to microelectronic dies and systems for processing the dies. The microelectronic dies can include micromechanical components, data storage elements, optics, read/write components, or other features. For example, the microelectronic dies can be SRAM, DRAM (e.g., DDR-SDRAM), flash-memory (e.g., NAND flash-memory), processors, imagers, and other types of devices. Moreover, several other embodiments of the invention can have different configurations, components, or procedures than those described in this section. A person of ordinary skill in the art, therefore, will accordingly understand that the invention may have other embodiments with additional elements, or the invention may have other embodiments without several of the elements shown and described below with reference to FIGS. 1-9.

FIG. 1 is a schematic side cross-sectional view of a system 100 for processing a semiconductor workpiece 108 having a plurality of microelectronic dies 110 in accordance with one embodiment of the disclosure. The illustrated workpiece 108 is a wafer that has been cut to singulate the dies 110. The individual dies 110 include an active side 112, a backside 114 opposite the active side 112, a plurality of terminals 116 (e.g., bond-pads) arranged in an array on the active side 112 and/or the backside 114, and an integrated circuit 118 (shown schematically) operably coupled to the terminals 116. The illustrated dies may have the same structure or different features to perform different functions.

The illustrated system 100 includes a support structure 130 for carrying the dies 110, a detachment apparatus 140 for at least partially detaching the dies 110 from the support structure 130, and a pick-and-place apparatus 190 for removing the dies 110 from the support structure 130. The support structure 130 is configured to releasably support the workpiece 108 during one or more processing procedures. For example, the illustrated support structure 130 includes a dicing support having an annular frame 132 carrying a releasable attachment member or film 134. The releasable film 134 has a first surface 135a and a second surface 135b opposite the first surface 135a. The illustrated support structure 130 also includes an adhesive 136 (e.g., UV tape) on the first surface 135a of the film 134 for releasably adhering the backsides 114 of the dies 110 to the film 134.

The detachment apparatus 140 can be positioned at the support structure 130 and aligned with a selected die 110 for at least partially detaching the die 110 from the support structure 130. The illustrated detachment apparatus 140 includes a support member 142 and a contact assembly 146 within the support member 142. The support member 142 has an opening 143 exposing the contact assembly 146 and a support surface 144 positioned to contact and support the second surface 135b of the releasable film 134. In other embodiments, the detachment apparatus 140 may not include the support member 142.

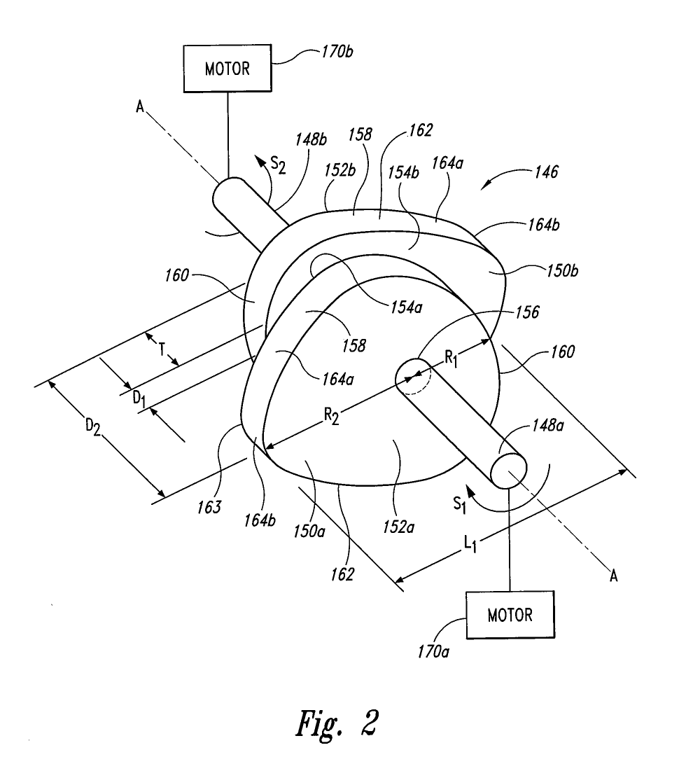

FIG. 2 is a schematic isometric view of the contact assembly 146. Referring to both FIGS. 1 and 2, the embodiment of the illustrated contact assembly 146 includes a first shaft 148a, a first contact member 150a attached to the first shaft 148a, a second shaft 148b (FIG. 2), and a second contact member 150b attached to the second shaft 148b. The first and second shafts 148a-b can be positioned in a co-axial arrangement and aligned with an axis A-A, but are spaced apart from each other such that the shafts 148 can rotate in opposite directions about the axis A-A. The first and second contact members 150a-b include outer surfaces 152 (identified individually as 152a-b), inner surfaces 154 (identified individually as 154a-b), an aperture 156 sized to receive the corresponding shaft 148, and a thickness T between the outer and inner surfaces 152 and 154. The outer surfaces 152 and the inner surfaces 154 can be generally planar. The inner surfaces 154a-b of the first and second contact members 150a-b are spaced apart by a first distance D₁, and the outer surfaces 152a-b of the first and second contact members 150a-b are spaced apart by a second distance D₂. The second distance D₂ may be approximately equal to or less than a transverse dimension of the individual dies 110, and the individual contact members 150 have a length L₁ that is approximately equal to 75% of a length L₂ of the individual dies 110. In other embodiments, the contact members 150 may have a different size and/or configuration.

The embodiment of the illustrated first and second contact members 150a-b are cams with an arcuate surface 158 positioned to contact the second surface 135b of the releasable film 134. The arcuate surface 158 can extend between the outer and inner surfaces 152 and 154 and include a first section 160 with a generally uniform first radius of curvature and a second section 162 with a variable radius of curvature. In one specific embodiment, the second section 162 of the arcuate surface 158 includes a first portion 164a with a second radius of curvature greater than the first radius of curvature and a second portion 164b with a third radius of curvature less than the first radius of curvature. As such, such examples of the contact members 150a-b have a first dimension R₁ between the aperture 156 and the first section 160, and a second dimension R₂ between the aperture 156 and the second portion 164b. In other embodiments, the contact members 150 can have a different configuration. In either case, the first and second contact members 150a-b are attached to the first and second shafts 148a-b, respectively, in an eccentric arrangement.

In the illustrated embodiment, the detachment apparatus 140 further includes a first motor 170a operably coupled to the first shaft 148a and a second motor 170b (FIG. 2) operably coupled to the second shaft 148b. The first motor 170a is configured to rotate the first shaft 148a and the first contact member 150a in a first direction S₁ about the axis A-A, and the second motor 170b is configured to rotate the second shaft 148b and the second contact member 150b in a second direction S₂ about the axis A-A. The first and second motors 170a-b can rotate the first and second contact members 150a-b, respectively, at a generally constant angular velocity or at a variable angular velocity. In other embodiments, the motors 170 can rotate the contact members 150 in the same direction, or the detachment apparatus 140 may include only a single contact member 150 for detaching each die 110. In still other embodiments, the detachment apparatus 140 may have a single motor, first and second contact member 150a and 150b, and gearing, linkage or another transfer system that couples the output of the motor to the contact members 150a-b either independently or together.

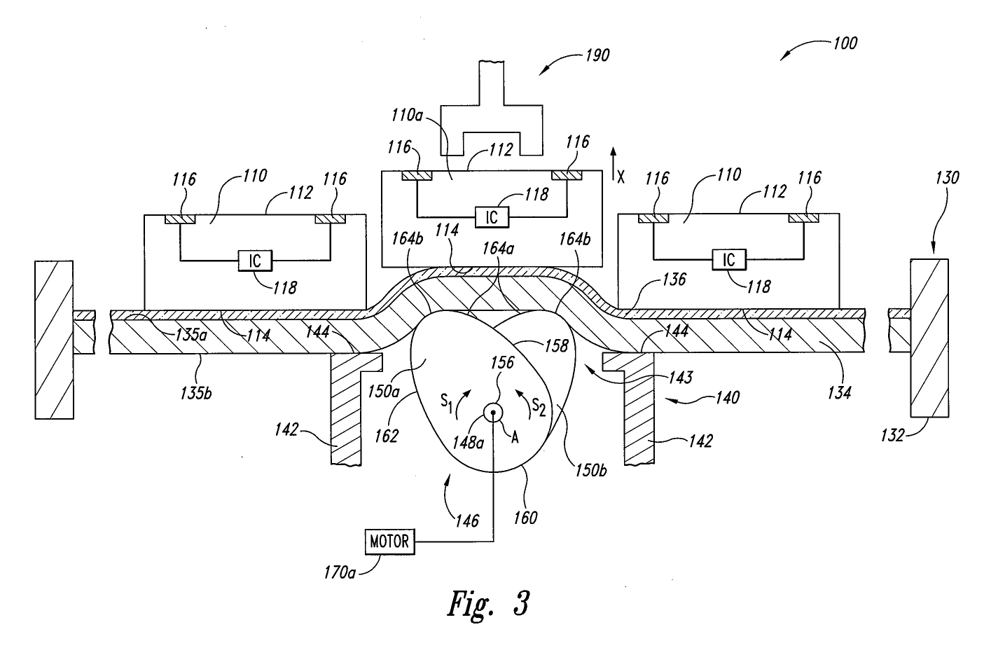

FIGS. 3-5 illustrate stages in a method for detaching a first die 110a from the support structure 130 in accordance with one embodiment of the disclosure. For example, FIG. 3 is a schematic side cross-sectional view of the system 100 after pivoting the contact assembly 146 from (a) a first position (shown in FIG. 1) in which the releasable film 134 and the first die 110a are not displaced to (b) a second position in which the releasable film 134 and the first die 110a are displaced. Specifically, as the first and second contact members 150a-b pivot about the axis A-A in the first and second directions S₁ and S₂, respectively, the first portions 164a of the arcuate surfaces 158 slide across the second surface 135b of the releasable film 134. Because the arcuate surfaces 158 of the contact members 150 are arranged eccentrically relative to the shafts 148, the arcuate surfaces 158 drive the portion of the film 134 at the points of contact and the first die 110a in a direction X generally normal to a plane defined by the unflexed releasable film 134. As the releasable film 134 flexes, portions of the film 134 adjacent to the points of contact detach from the first die 110a.

In a specific embodiment, which is merely one example and is not intended to be limiting, the first portions 164a of the arcuate surfaces 158 contact a surface area of the releasable film 134 along a dimension that is approximately 70% to approximately 80% of a width of the corresponding die above the first portions 164a. The rotational velocity and/or the second dimensions R₂ can be configured to provide a gradual displacement of the releasable film 134 and the die 110 so that the edge portions of the die 110 can be safely decoupled from the releasable film 134. In another specific embodiment, which is merely another example and is not intended to be limiting, the rotational velocity of the first and second contact members 150a-b can be controlled such that the displacement velocity of the die 110 or the releasable film 134 in the direction X can be approximately 5-10 mm/s. In still another specific embodiment, which is merely another example and is not intended to be limiting, the rotational velocity and/or the shape of the contact members 150 can also be controlled such that the force exerted by the contact members against the releasable film 134 is approximately 0.5 N to approximately 0.8 N. Additionally, any of the foregoing specific embodiments in this paragraph may stand alone or be used in combination with each other.

FIG. 4 is a schematic side cross-sectional view of the system 100 after rotating the contact assembly 146 from the second position (shown in FIG. 3) to a detach position. In the detach position, the distal ends 163 of the contact members 150 are positioned against the releasable film 134 and much of the film 134 adjacent to the first die 110a has detached from the first die 110a. After the detachment apparatus 140 has at least partially decoupled the first die 110a from the releasable film 134, the pick-and-place apparatus 190 grasps the active side 112 of the die 110a and removes the die 110a from the support structure 130.

FIG. 5 is a schematic side cross-sectional view of the system 100 after rotating the contact assembly 146 from the detach position (shown in FIG. 4) to a third position. As the first and second contact members 150a-b pivot from the detach position to the third position, the releasable film 134 returns to a generally unflexed position. In several embodiments, the contact members 150 may not contact the releasable film 134 when the members 150 pivot from the third position back to the first position. In other embodiments, the contact members 150 may contact but not significantly displace the releasable film 134 as the members 150 rotate from the third position to the first position. In either case, the detachment apparatus 140 can move relative to the support structure 130 to align the contact assembly 146 with another die 110 after the pick-and-place apparatus 190 has secured the first die 110a.

Several embodiments of the system 100 illustrated in FIGS. 1-5 may to at least partially detach one or more dies 110 from the releasable film 134 without cracking or otherwise damaging the dies 110. Because the contact members 150 have a thickness T, the forces exerted on the dies 110 by the contact members 150 are distributed over a surface area sufficiently large to reduce or avoid cracking of the dies 100. The surface area, however, is still small enough to detach the dies 110 from the film 134. As such, the system 100 is expected to increase the yield of the dies 110.

Several embodiments of the system 100 illustrated in FIGS. 1-5 may to increase the throughput of the production process. Specifically, the contact members 150 include an arcuate surface 158 with a first portion 164a and a second portion 164b. The first portion 164a is positioned to exert a force on the releasable film 134 and the die 110 when the backside 114 of the die 110 is completely attached to the film 134. The curvature of the first portion 164a is shaped to move the die 110 in the direction X at a first speed. The second portion 164b is positioned to exert a force on the releasable film 134 and the die 110 when the backside 114 of the die 110 is partially detached from film 134. The curvature of the second portion 164b is shaped to move the die 110 in the direction X at a second speed greater than the first speed. The contact members 150 accordingly move the die 110 at an initial speed when the die 110 is completely attached to the releasable film 134 and more susceptible to cracking, and a faster speed when the die 110 is partially detached from the film 134 and less likely to crack. As a result, the system 100 can detach dies 110 at a faster rate to increase throughput.

Several embodiments of the system 100 can be used to decouple a microelectronic die from a first side of a releasable film by applying a first force against a second side of the releasable film to move the microelectronic die in a first direction at a first speed. After applying the first force, the method includes applying a second force against the second side of the releasable film to move the microelectronic die in the first direction at a second speed different than the first speed.

Another embodiment of a method for processing a semiconductor workpiece using an embodiment of the system 100 includes releasably attaching a plurality of microelectronic dies to a first side of a releasable film, and at least partially detaching one of the microelectronic dies from the releasable film by pivoting a contact member with a surface of the contact member pressing against a second side of the releasable film. The system 100 can also be used in another method for processing a microelectronic die that includes providing the die on a first side of a releasable attachment member, contacting a second side of the releasable attachment member with an arcuate surface, and moving the arcuate surface relative to the attachment member to at least partially decouple the die from the attachment member.

The system 100 can also have embodiments in which the system includes a support member configured to carry the releasable film, and a contact assembly including a cam positioned to contact the releasable film.

In another embodiment, the system 100 includes a support member for carrying the releasable film, and a contact assembly having a shaft and a contact member coupled to the shaft. The contact member has a surface positioned to contact the releasable film. The system further includes a motor operably coupled to the shaft to pivot the shaft and move the surface of the contact member relative to the releasable film.

Still other embodiments of the system 100 include a support member configured to carry the releasable film, and means for applying a first force against the releasable film to urge the die in a first direction at a first speed and subsequently applying a second force against the releasable film to urge the die in the first direction at a second speed different than the first speed.

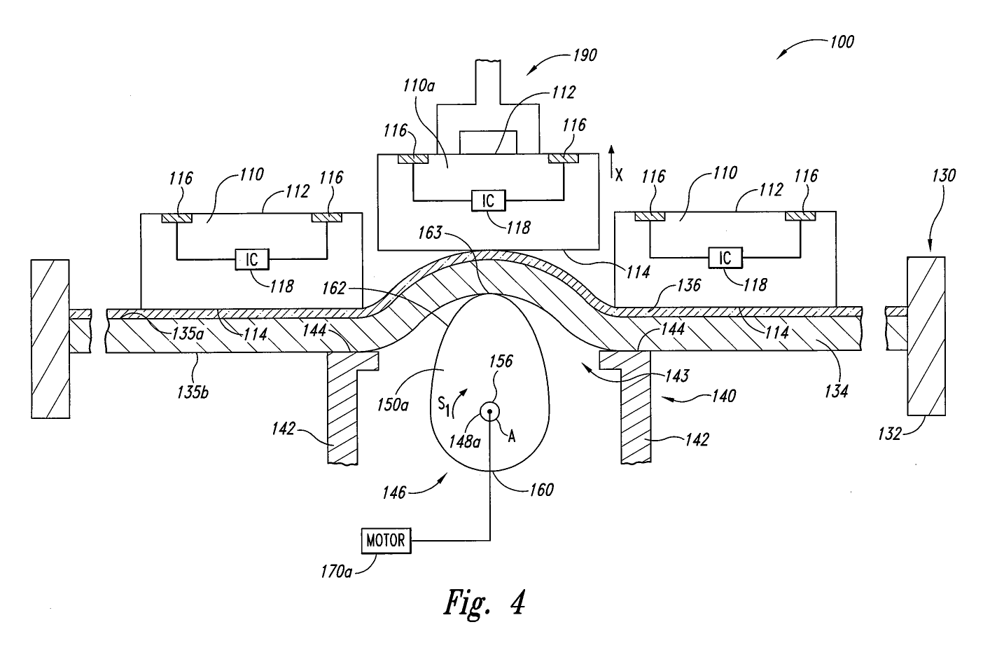

FIG. 6 is a schematic isometric view of a contact assembly 246 in accordance with another embodiment of the disclosure. The illustrated contact assembly 246 is generally similar to the contact assembly 146 described above with reference to FIGS. 1 and 2. For example, the illustrated contact assembly 246 includes first and second contact members 250a-b having an arcuate surface 258 with a first section 260 and a second section 262. The second section 262 in the illustrated embodiment, however, includes a groove 266 and a plurality of ball bearings 268 received in the groove 266. The groove 266 is configured to retain the bearings 268 within the groove 266 while allowing the bearings 268 to spin. The ball bearings 268 are positioned to project a short distance from the groove 266 and contact the second surface 135b (FIG. 1) of the releasable film 134 (FIG. 1). The ball bearings 268 may reduce friction between the arcuate surface 258 and the second surface 135b of the releasable film 134 and thereby reduce or eliminate the concomitant distortion or damage of the film 134. In other embodiments, the first section 260 of the arcuate surface 258 may also include the groove 266 and the ball bearings 268. In additional embodiments, the contact assembly 246 can include a lubricant on the contact surfaces, a low-friction coating (e.g., Teflon) on the contact surfaces, and/or a different device (e.g., cylindrical rollers instead of ball bearings) for reducing friction between the contact members 250 and the releasable film 134.

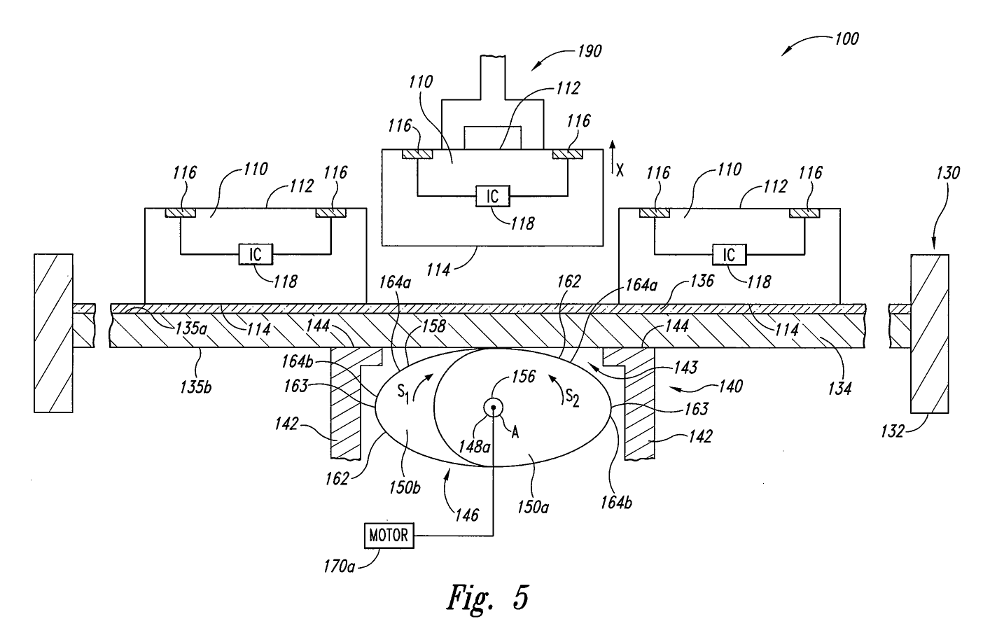

FIGS. 7-9 are schematic side views of different profiles of contact members in accordance with several embodiments of the disclosure. For example, FIG. 7 is a schematic side view of a contact member 350 having an arcuate surface 358 with a first section 160 and a second section 362. The illustrated contact member 350 is generally similar to the contact members 150 described above with reference to FIGS. 1 and 2. The illustrated contact member 350, however, has a greater radius of curvature at a distal end 363. As such, the illustrated contact member 350 is expected to displace the releasable film 134 and the die 110 at a slower rate when the contact member 350 approaches the detach position.

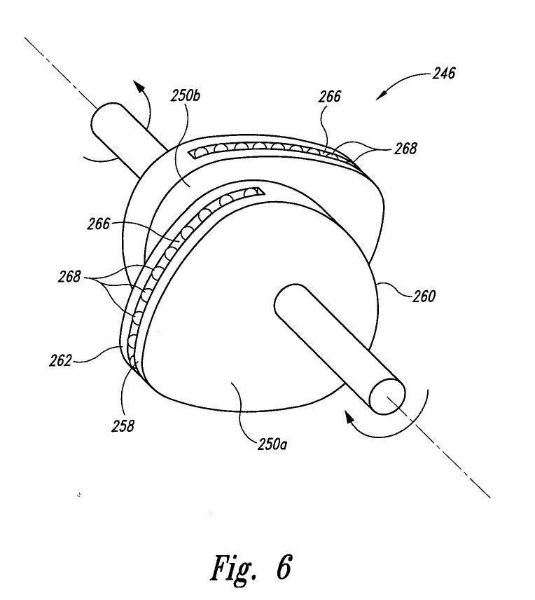

FIG. 8 is a schematic side view of a contact member 450 in accordance with another embodiment of the disclosure. The contact member 450 is generally similar to the contact member 150 described above with reference to FIGS. 1 and 2. For example, the contact member 450 includes an arcuate surface 458 having a first section 160 and a second section 462. The illustrated second section 462, however, includes a generally flat surface 464 at a distal end 463. The flat surface 464 may provide a surface on which the die 110 can rest while the pick-and-place apparatus 190 grasps the die 110.

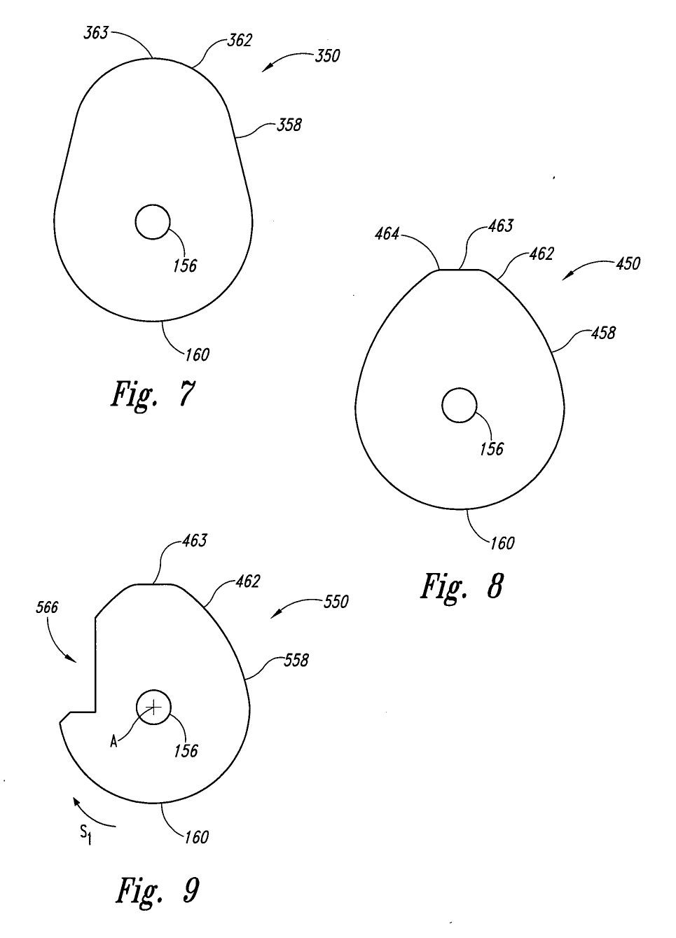

FIG. 9 is a schematic side view of a contact member 550 in accordance with another embodiment of the disclosure. The illustrated contact member 550 is generally similar to the contact member 450 described above with reference to FIG. 8. The illustrated contact member 550, however, includes a cutout portion 566 in the second section 462 of the arcuate surface 558. The cutout section 566 enables the releasable film 134 to abruptly drop when the contact member 550 rotates from the detach position to the third position. This may facilitate the detachment of the releasable film 134 from the die 110. In other embodiments, the contact member may have a different profile shaped to meet certain process requirements.

From the foregoing, it will be appreciated that specific embodiments of the invention have been described herein for purposes of illustration, but that various modifications may be made without deviating from the invention. For example, many of the elements of one embodiment can be combined with other embodiments in addition to or in lieu of the elements of the other embodiments. Additionally, the backside of the releasable film can be coated with a lubricant or a low-friction material. Accordingly, the invention is not limited except as by the appended claims.

1. A method for processing a semiconductor workpiece, the method comprising:
releasably attaching a microelectronic die to a first side of a releasable film; and
pivoting a contact member such that a surface of the contact member presses against a second side of the releasable film and detaches the die from the releasable film.

2. The method of claim 1 wherein:
the contact member comprises a cam; and
pivoting the contact member comprises pressing the cam against the second side of the releasable film.

3. The method of claim 1 wherein:
the contact member comprises a first contact member; and
the method further comprises pivoting a second contact member such that a surface of the second contact member presses against the second side of the releasable film adjacent to the die.

4. The method of claim 1 wherein:
the contact member comprises a first contact member;
pivoting the first contact member comprises rotating the first contact member about an axis in a first direction; and
the method further comprises rotating a second contact member about the axis in a second direction such that a surface of the second contact member presses against the second side of the releasable film adjacent to the die, the second direction being opposite the first direction.

5. The method of claim 1 wherein:
the surface of the contact member comprises a generally flat section; and
pivoting the contact member comprises pressing the generally flat section against the second side of the releasable film.

6. The method of claim 1 wherein:
the surface of the contact member comprises an arcuate section arranged eccentrically about an axis of rotation; and
pivoting the contact member comprises pressing the arcuate section against the second side of the releasable film.

7. The method of claim 1 wherein:
the surface of the contact member comprises a generally flat section and an arcuate section; and
pivoting the contact member comprises pressing the generally flat section against the second side of the releasable film and pressing the arcuate section against the second side of the releasable film.

8. The method of claim 1 wherein:
the surface of the contact member comprises a first arcuate section with a first radius of curvature and a second arcuate section with a second radius of curvature different than the first radius of curvature; and
pivoting the contact member comprises pressing the first arcuate section against the second side of the releasable film and pressing the second arcuate section against the second side of the releasable film.

9. The method of claim 1 wherein:
the contact member comprises a plurality of ball bearings; and
pivoting the contact member comprises contacting the second side of the releasable film with the ball bearings.

10. A method for decoupling a microelectronic die from a first side of a film, the method comprising:
applying a first force against a second side of the releasable film such that the microelectronic die moves in a first direction at a first speed; and
after applying the first force, applying a second force against the second side of the film such that the microelectronic die moves in the first direction at a second speed different than the first speed.

11. The method of claim 10 wherein:
applying the first force against the film comprises pivoting a contact member about an axis in a first direction over a first angle; and
applying the second force against the film comprises pivoting the contact member about the axis in the first direction over a second angle.

12. The method of claim 10 wherein:
applying the first force against the film comprises pressing a cam against the film; and
applying the second force against the film comprises pressing the cam against the film.

13. The method of claim 10 wherein:
applying the first force against the film comprises pivoting a contact member about an axis at a first angular velocity; and
applying the second force against the film comprises pivoting the contact member about the axis at the first angular velocity.

14. The method of claim 10 wherein:
applying the first force against the film comprises pressing a first cam against the releasable film;
applying the second force against the releasable film comprises pressing the first cam against the releasable film; and
the method further comprises pressing a second cam against the releasable film at the die while pressing the first cam against the releasable film.

15. The method of claim 10 wherein:
the releasable film defines a plane;
applying the first force against the releasable film comprises moving the die in a direction generally normal to the plane; and
applying the second force against the releasable film comprises moving the die in the direction generally normal to the plane.

16. A method for processing a microelectronic die attached to a first side of a releasable attachment member, the method comprising:
contacting a second side of the releasable attachment member with an arcuate surface; and
moving the arcuate surface relative to the releasable attachment member to at least partially decouple the microelectronic die from the releasable attachment member, the second side being opposite the first side.

17. The method of claim 16 wherein contacting the second side of the releasable attachment member comprises pressing a cam having the arcuate surface against the second side of the releasable attachment member.

18. The method of claim 16 wherein contacting the second side of the releasable attachment member comprises pivoting a contact member having the arcuate surface.

19. The method of claim 16, wherein before contacting the second side of the releasable attachment member with an arcuate surface, the method further comprises:
thinning a semiconductor workpiece; and
cutting the semiconductor workpiece to singulate a plurality of dies with the workpiece attached to a first side of a releasable attachment member.

20-36. (canceled)
